(19) United States
(12) Patent Application Publication
(10) Pub. No.: US 2026/0096320 A1
(43) Pub. Date: Apr. 2, 2026

(54) DISPLAY PANEL, MANUFACTURING METHOD OF THE SAME, AND DISPLAY DEVICE

(71) Applicant: HKC CORPORATION LIMITED, SHENZHEN (CN)

(72) Inventors: Dongmei WEI, SHENZHEN (CN); Haijiang YUAN, SHENZHEN (CN)

(73) Assignee: HKC CORPORATION LIMITED, SHENZHEN (CN)

(21) Appl. No.: 19/334,647

(22) Filed: Sep. 19, 2025

(30) Foreign Application Priority Data
Sep. 30, 2024 (CN) 202411389981.3

(51) Int. Cl. H10K 59/131; H10K 59/12; H10K 59/122; H10K 59/80; H10K 71/60

(52) U.S. Cl. CPC H10K 59/131; H10K 59/1201; H10K 59/122; H10K 59/873; H10K 71/60

(57) ABSTRACT

A display panel, a manufacturing method of the same, and a display device. The display panel includes: a drive circuit backplate, a light-emitting unit carrier plate, and an encapsulation layer. The light-emitting unit carrier plate includes: a first substrate, defining vias; a pixel definition layer, disposed on the first substrate; a plurality of organic light-emitting diode devices, each of which includes an anode film layer, a light-emitting layer, and a cathode film layer; and bonding portions. Each bonding portion is disposed in a corresponding via, and the bonding portion is electrically connected to the anode film layer and the cathode film layer. The encapsulation layer includes: a first encapsulation layer and a second encapsulation layer; the first encapsulation layer encapsulates the organic light-emitting diode devices; the second encapsulation layer encapsulates the light-emitting unit carrier plate and a gap between the drive circuit backplate and the light-emitting unit carrier plate.

### CROSS-REFERENCE TO RELATED APPLICATIONS

The present application claims priority of Chinese Patent Application No. 202411389981.3, filed on Sep. 30, 2024, the entire contents of which are hereby incorporated by reference in their entirety.

### TECHNICAL FIELD

The present disclosure relates to the field of optical display technologies, and in particular to a display panel, a manufacturing method of the same, and a display device.

### BACKGROUND

In the related art, silicon-based Organic Light-Emitting Diode (OLED) display panels are active-matrix OLED display elements utilizing Complementary Metal Oxide Semiconductor (CMOS) devices as driving units. These panels integrate traditionally externally-bonded display chips into a silicon-based backplate. By depositing a pixel pattern isolation layer on the silicon-based CMOS driving substrate, followed by vapor-deposition of an anode, a light-emitting layer, and a cathode, smaller pixel dimensions can be achieved, thereby enabling refined display pixelation. This technology has been widely applied in military applications such as head-mounted displays, gun sights, and night vision devices. However, the vapor-deposition process of the light-emitting layer may adversely affect the silicon-based driving circuits, potentially rendering them inoperative and increasing manufacturing costs. Therefore, there is a critical need for innovative silicon-based OLED architectures to enhance production yield and reduce fabrication expenses.

### SUMMARY OF THE DISCLOSURE

The purpose of the present disclosure is to provide a display panel, a manufacturing method of the same, and a display device.

A display panel, including:
a drive circuit backplate, including a drive circuit layer;
a light-emitting unit carrier plate, including:
   a first substrate, defining a plurality of vias;
   a pixel definition layer, disposed on the first substrate; wherein the pixel definition layer forms a plurality of pixel regions that are spaced apart, and orthogonal projections of the plurality of pixel regions on the first substrate are overlapped with orthogonal projections of some of the plurality of vias on the first substrate;
   a plurality of organic light-emitting diode devices; wherein each organic light-emitting diode device includes an anode film layer, a light-emitting layer, and a cathode film layer that are arranged in sequence from a side close to the drive circuit backplate toward a side away from the drive circuit backplate; the anode film layer, the light-emitting layer, and the cathode film layer of each organic light-emitting diode device are disposed in a corresponding pixel region; on a side of the first substrate away from the drive circuit backplate, the cathode film layer extends outside the plurality of pixel regions and covers the pixel definition layer; and
   a plurality of bonding portions; wherein each bonding portion is disposed in a corresponding via, and the bonding portion is electrically connected to the anode film layer and the cathode film layer of a corresponding organic light-emitting diode device; the bonding portion protrudes from the first substrate toward the drive circuit backplate; in a case where the drive circuit backplate is connected to the light-emitting unit carrier plate, the bonding portion abuts against the drive circuit layer, and a gap exists between the drive circuit backplate and the light-emitting unit carrier plate; and
an encapsulation layer, including: a first encapsulation layer and a second encapsulation layer; wherein the first encapsulation layer is disposed on the cathode film layer, and in a direction from the cathode film layer to the first substrate, the first encapsulation layer extends onto the first substrate to encapsulate the plurality of organic light-emitting diode devices on the first substrate; the second encapsulation layer is disposed on the first encapsulation layer, and in a direction from the cathode film layer to the drive circuit backplate, the second encapsulation layer extends onto the drive circuit backplate to encapsulate the light-emitting unit carrier plate on the drive circuit backplate and encapsulate the gap between the drive circuit backplate and the light-emitting unit carrier plate.

A manufacturing method of a display panel, including:
preparing a drive circuit backplate; wherein the drive circuit backplate includes a drive circuit layer;
preparing a light-emitting unit carrier plate, including:
   defining a plurality of vias on a first substrate;
   preparing a pixel definition layer on the first substrate; wherein the pixel definition layer forms a plurality of pixel regions that are spaced apart, and orthogonal projections of the plurality of pixel regions on the first substrate are overlapped with orthogonal projections of some of the plurality of vias on the first substrate;
   forming a plurality of organic light-emitting diode devices in the plurality of pixel regions; wherein each organic light-emitting diode device includes an anode film layer, a light-emitting layer, and a cathode film layer that are arranged in sequence from a side close to the drive circuit backplate toward a side away from the drive circuit backplate; the anode film layer, the light-emitting layer, and the cathode film layer of each organic light-emitting diode device are disposed in a corresponding pixel region; on a side of the first substrate away from the drive circuit backplate, the cathode film layer extends outside the plurality of pixel regions and covers the pixel definition layer; and
   preparing a bonding portion in each via; where the bonding portion is electrically connected to the anode film layer and the cathode film layer of a corresponding organic light-emitting diode device; the bonding portion protrudes from the first substrate toward the drive circuit backplate;
preparing a first encapsulation layer on the cathode film layer; wherein in a direction from the cathode film layer to the first substrate, the first encapsulation layer extends onto the first substrate to encapsulate the plurality of organic light-emitting diode devices on the first substrate;
connecting the drive circuit backplate to the light-emitting unit carrier plate; wherein the bonding portion abuts against the drive circuit layer, and a gap exists between the drive circuit backplate and the light-emitting unit carrier plate; and
preparing a second encapsulation layer on the first encapsulation layer; wherein in a direction from the cathode film layer to the drive circuit backplate, the second encapsulation layer extends onto the drive circuit backplate to encapsulate the light-emitting unit carrier plate on the drive circuit backplate and encapsulate the gap between the drive circuit backplate and the light-emitting unit carrier plate.

A display device, including the display panel above.

### BRIEF DESCRIPTION OF THE DRAWINGS

The accompanying drawings are incorporated into the specification and form an integral part thereof, illustrating embodiments of the present disclosure and, together with the specification, serving to explain the principles of the present disclosure. It will be apparent from the accompanying drawings that the embodiments described herein are merely some examples of the present disclosure, and that other drawings may be obtained by those skilled in the art without creative labor based on these drawings.

FIG. 1 is a first structural schematic view of a display panel according to some embodiments of the present disclosure.

FIG. 2 is a second structural schematic view of a display panel according to some embodiments of the present disclosure.

FIG. 3 is a first flowchart of manufacturing method of a display panel according to some embodiments of the present disclosure.

FIG. 4 is a second flowchart of manufacturing method of a display panel according to some embodiments of the present disclosure.

FIG. 5 is a first flowchart of preparing a drive circuit backplate according to some embodiments of the present disclosure.

FIG. 6 is a second flowchart of preparing a drive circuit backplate according to some embodiments of the present disclosure.

FIG. 7 is a first flowchart of preparing a light-emitting unit carrier plate according to some embodiments of the present disclosure.

FIG. 8 is a second flowchart of preparing a light-emitting unit carrier plate according to some embodiments of the present disclosure.

FIG. 9 is a third flowchart of preparing a light-emitting unit carrier plate according to some embodiments of the present disclosure.

FIG. 10 is a fourth flowchart of preparing a light-emitting unit carrier plate according to some embodiments of the present disclosure.

FIG. 11 is a fifth flowchart of preparing a light-emitting unit carrier plate according to some embodiments of the present disclosure.

### DETAILED DESCRIPTION

The exemplary embodiments will now be described in greater detail with reference to the accompanying drawings. However, the exemplary embodiments may be implemented in various forms and should not be limited to the examples described herein; rather, the provision of these embodiments is intended to make the present disclosure more comprehensive and complete and to convey the concept of the exemplary embodiments to those skilled in the art.

Furthermore, the features, structures, or characteristics described may be combined in any suitable manner in one or more embodiments. In the following description, many specific details are provided to give a thorough understanding of the embodiments of the present disclosure. However, those skilled in the art will realize that the technical solutions of the present disclosure may be practiced without one or more of the specific details, or that other methods, components, devices, steps, etc. may be used. In other cases, well-known methods, apparatuses, implementations, or operations are not shown or described in detail to avoid obscuring the various aspects of the present disclosure.

The present disclosure is further described below with reference to the accompanying drawings and specific embodiments. It should be noted that the technical features described in the various embodiments of the present disclosure may be combined with each other as long as they do not conflict with each other. The embodiments described below with reference to the accompanying drawings are exemplary and are intended to explain the present disclosure and should not be understood as limiting the present disclosure.

It should be noted that “multiple” as used herein refers to two or more. “And/or” describes a relationship between associated objects, indicating that three relationships may exist. For example, “A and/or B” may indicate: A exists alone, A and B exist together, or B exists alone. The character “/” generally indicates that the associated objects before and after it are in an “or” relationship.

In the related art, silicon-based Organic Light-Emitting Diode (OLED) display panels are active-matrix OLED display elements utilizing Complementary Metal Oxide Semiconductor (CMOS) devices as driving units. These panels integrate traditionally externally-bonded display chips into a silicon-based backplate. By depositing a pixel pattern isolation layer on the silicon-based CMOS driving substrate, followed by vapor-deposition of an anode, a light-emitting layer, and a cathode, smaller pixel dimensions can be achieved, thereby enabling refined display pixelation. This technology has been widely applied in military applications such as head-mounted displays, gun sights, and night vision devices. However, the vapor-deposition process of the light-emitting layer may adversely affect the silicon-based driving circuits, potentially rendering them inoperative and increasing manufacturing costs. Therefore, there is a critical need for innovative silicon-based OLED architectures to enhance production yield and reduce fabrication expenses.

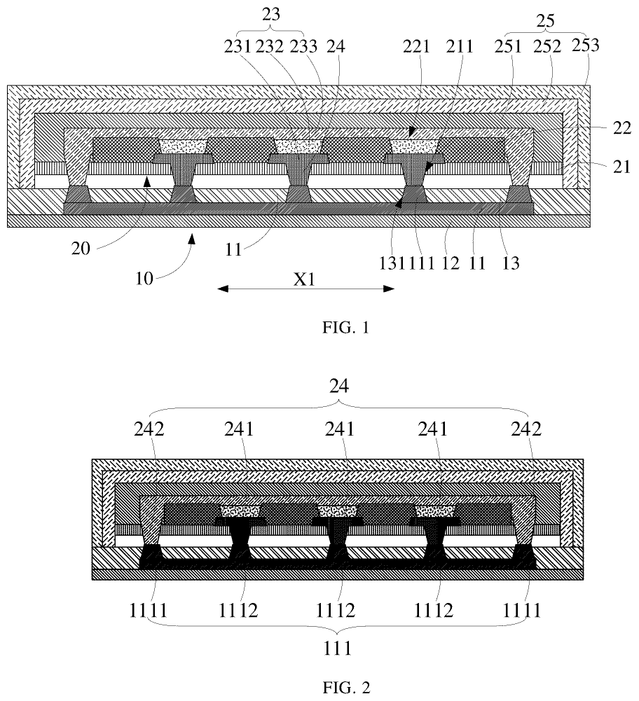

To address the aforementioned technical issues, the present disclosure provides a display panel. Referring to FIG. 1, the display panel includes a drive circuit backplate 10, a light-emitting unit carrier plate 20, and an encapsulation layer 25. The drive circuit backplate 10 and the light-emitting unit carrier plate 20 are connected together using a bonding process, and the drive circuit backplate 10 and/or the light-emitting unit carrier plate 20 are encapsulated by the encapsulation layer 25.

Referring to FIG. 1, the drive circuit backplate 10 includes a drive circuit layer 11; the light-emitting unit carrier plate 20 includes a first substrate 21, a pixel definition layer 22, multiple organic light-emitting diode devices 23, and multiple bonding portions 24; the first substrate 21 defines multiple vias 211; the pixel definition layer 22 is disposed on the first substrate 21, the pixel definition layer 22 forms pixel regions 221 that are spaced apart, and orthogonal projections of the pixel regions 221 on the first substrate 21 are overlapped with orthogonal projections of some of the vias 211; each of the organic light-emitting diode devices 23 includes an anode film layer 231, a light-emitting layer 232, and a cathode film layer 233 that are arranged in sequence from a side close to the drive circuit backplate 10 toward a side away from the drive circuit backplate 10; the anode film layer 231, the light-emitting layer 232, and the cathode film layer 233 of each organic light-emitting diode device 23 are disposed in a corresponding pixel region 221; the anode film layer 231 and the light-emitting layer 232 are separated by the pixel defining layer 22; the cathode film layer 233 is a full-surface structure, and on a side of the first substrate 21 away from the drive circuit backplate 10, the cathode film layer 233 extends outside the pixel region 221 and covers the pixel definition layer 22; each bonding portion 24 is disposed in a corresponding via 211, and the bonding portion 24 is electrically connected to the anode film layer 231 and the cathode film layer 233 of a corresponding organic light-emitting diode device 23; the bonding portion 24 protrudes from the first substrate 21 toward the drive circuit backplate 10. When the drive circuit backplate 10 is connected to the light-emitting unit carrier plate 20, the bonding portion 24 abuts against the drive circuit layer 11, and a gap exists between the drive circuit backplate 10 and the light-emitting unit carrier plate 20. The encapsulation layer 25 includes a first encapsulation layer 251 and a second encapsulation layer 252; the first encapsulation layer 251 is disposed on the cathode film layer 233, and in a direction from the cathode film layer 233 to the first substrate 21, the first encapsulation layer 251 extends onto the first substrate 21 to encapsulate the organic light-emitting diode devices 23 on the first substrate 21; the second encapsulation layer 252 is disposed on the first encapsulation layer 251, and in a direction from the cathode film layer 233 to the drive circuit backplate 10, the second encapsulation layer 252 extends onto the drive circuit backplate 10 to encapsulate the light-emitting unit carrier plate 20 on the drive circuit backplate 10 and encapsulate the gap between the drive circuit backplate 10 and the light-emitting unit carrier plate 20.

Referring to FIG. 1, the drive circuit backplate 10 and the light-emitting unit carrier plate 20 are prepared separately, and the drive circuit backplate 10 is connected to the light-emitting unit carrier plate 20 by the abutment between the bonding portion 24 and the drive circuit layer 11. This design may avoid directly depositing the light-emitting layer 232 on the drive circuit layer 11 and enable the light-emitting unit carrier plate 20 to emit light driven by the drive circuit backplate 10, thereby improving yield during the manufacturing process and reducing manufacturing costs. During the bonding (connecting) process of the drive circuit backplate 10 and the light-emitting unit carrier plate 20, since the pixel regions 221 are encapsulated and covered by the first encapsulation layer 251, the first encapsulation layer 251 serves to protect the light-emitting layers 232. After the drive circuit backplate 10 and the light-emitting unit carrier plate 20 are completely connected, the second encapsulation layer 252 encapsulates the light-emitting unit carrier plate 20 on the drive circuit backplate 10 and encapsulates the gap between the drive circuit backplate 10 and the light-emitting unit carrier plate 20. The second encapsulation layer 252 may protect the bonding points between the two substrates, thereby improving the overall reliability of the product and ensuring display quality.

In some embodiments, the first substrate 21 is a glass substrate, which may improve the light transmittance of the display panel and increase its brightness. Holes may be prepared on the first substrate 21 by laser drilling, or by exposure, development, and etching.

In some embodiments, the pixel definition layer 22 includes an inorganic material, which is deposited using plasma-enhanced chemical vapor deposition, followed by a series of processes including exposure, development, and etching to form the pixel regions 221.

In some embodiments, as shown in FIG. 1, materials of the anode film layer 231, the light-emitting layer 232, and the cathode film layer 233 of the organic light-emitting diode device 23 are not specifically defined herein and may be selected according to actual conditions. During fabrication, after forming the pixel regions 221 on the first substrate 21 through exposure, development, and etching, the material of the anode film layer 231 is first vapor-deposited to form the anode film layer 231, followed by vapor-depositing the material of the light-emitting layer 232 to form the light-emitting layer 232, and finally vapor-depositing the material of the cathode film layer 233 to form the cathode film layer 233.

In some embodiments, during vapor-deposition, different deposition angles may be adopted to vapor-deposit the anode film layer 231, the light-emitting layer 232, and the cathode film layer 233, such that the anode film layer 231, the light-emitting layer 232, and the cathode film layer 233 have different areas within the pixel region 221.

In some embodiments, as shown in FIG. 1, the materials of the anode film layer 231 and the light-emitting layer 232 are vapor-deposited in the pixel region 221 to sequentially form the anode film layer 231 and the light-emitting layer 232. The material of cathode film layer 233 is further vapor-deposited on a side opposite to the anode film layer 231 and the light-emitting layer 232, thereby forming a continuous film layer structure on the surface of the pixel definition layer 22 to cover the pixel definition layer 22. In a radial direction, the cathode film layer 233 is vapor-deposited on the outer side of the pixel definition layer 22, and in an axial direction, the cathode film layer 233 extends along the outer side of the pixel definition layer 22. As a result, the cathode film layer 233 designed in this manner may reduce voltage drop and reduce the difficulty of manufacturing the display panel.

In some embodiments, the direction from the cathode film layer 233 toward the first substrate 21 and the direction from the cathode film layer 233 toward the drive circuit backplate 10 are the same or substantially the same as the axial direction, and the radial direction is perpendicular to the axial direction.

In some embodiments, as shown in FIG. 1, the bonding portion 24 is configured to provide electrical conductivity between the anode film layer 231, the cathode film layer 233, and the drive circuit backplate 10. Since the anode film layer 231 and the cathode film layer 233 require power supply from the drive circuit backplate 10, and the drive circuit backplate 10 is disposed on the side of the first substrate 21 away from the organic light-emitting diode device 23, the bonding portion 24 is required to be protruding toward the drive circuit backplate 10 from the first substrate 21.

In some embodiments, the bonding portion 24 may be formed by vapor deposition within the via 211 prior to forming the anode film layer 231, or may be formed by vapor deposition within the via 211 after forming the anode film layer 231.

In some embodiments, at least one bonding portion 24 may be an integral structure with its corresponding anode film layer 231. The material of the anode film layer 231 is deposited in the pixel region 221, and etching is performed to obtain the anode film layer 231. A portion of the material of the anode film layer 231 located in the via 211 is configured as an anode conductive portion. At least one bonding portion 24 may be an integral structure with its corresponding cathode film layer 233. When preparing the cathode film layer 233, the material of the cathode film layer is deposited in the pixel region 221, followed by exposure, development, and etching to form the cathode film layer 233. A portion of the material of the cathode film layer located in the via 211 is configured as a cathode conductive portion. In other embodiments, the anode film layer 231 and the cathode film layer 233 may be formed separately first, followed by the formation of bonding portions 24 corresponding to the anode film layer 231 and the cathode film layer 233. The specific process method may be selected based on actual conditions.

In some embodiments, as shown in FIG. 1, the encapsulation layer 25 further includes a third encapsulation layer 253, which is disposed on the second encapsulation layer 252. In the direction from the cathode film layer 233 to the drive circuit backplate 10, the third encapsulation layer 253 extends onto the drive circuit backplate 10. As a result, forming the third encapsulation layer 253 on the second encapsulation layer 252 may first reduce the thickness of the second encapsulation layer 252, thereby improving its quality, and may further cover the second encapsulation layer 252, thereby enhancing its encapsulation effectiveness. In other words, designing multiple thin encapsulation layers is more effective than designing a single thick encapsulation layer in terms of barrier performance. The multiple encapsulation layers form a denser barrier, effectively preventing the penetration of moisture and oxygen. Additionally, the multiple thin encapsulation layers offer higher flexibility and resistance to bending compared to a single thick encapsulation layer.

In some embodiments, as shown in FIG. 1, in a first direction X1, i.e., in a length direction of the display panel, a length of the drive circuit backplate 10 is greater than a length of the light-emitting unit carrier plate 20, such that the second encapsulation layer 252 and the third encapsulation layer 253 can be connected to the drive circuit when formed. The second encapsulation layer 252 and the third encapsulation layer 253 may further encapsulate the drive circuit layer 11 on the back, thereby protecting the drive circuit layer 11. In this way, the drive circuit layer 11 of the drive circuit backplate 10 and the bonding portion 24 of the light-emitting unit carrier plate 20 may be protected, thereby saving materials, reducing the number of process steps, and improving the overall reliability of the product while ensuring display quality.

In some embodiments, the first encapsulation layer 251, the second encapsulation layer 252, and the third encapsulation layer 253 may be organic materials or inorganic materials, selected based on actual conditions.

In some embodiments, as shown in FIG. 1, the diameter of each pixel region 221 gradually increases along a direction from a side close to the first substrate 21 to a side away from the first substrate 21. The shape of the pixel region 221 may be similar to a trapezoidal body, a frustum, etc. In the present disclosure, a frustum is taken as an example for illustration. As described above, the pixel region 221 is a structure for depositing the organic light-emitting diode device 23. To provide a larger light-emitting area for the organic light-emitting diode device 23, the diameter of the pixel region 221 is required to be sufficiently large. However, to ensure the stability of other structures, the diameter, also the aperture area, of the pixel region 221 cannot be arbitrarily enlarged. Therefore, the proposed design solution may achieve this by designing the pixel region 221 as a hole structure with a gradually increasing diameter, thereby enabling a larger light-emitting area on the side farther from the first substrate 21.

In some embodiments, as shown in FIG. 1, the drive circuit backplate 10 includes a second substrate 12, a drive circuit layer 11, and a protective layer 13. The drive circuit layer 11 is disposed on the second substrate 12, and the protective layer 13 is disposed on the drive circuit layer 11; the protective layer 13 defines multiple through holes 131; the drive circuit layer 11 includes multiple connection portions 111, and each of the connection portions 111 passes through a corresponding through hole 131; the connection portions 111 protrude from the protective layer 13 toward the first substrate 21, and each of the connection portions 111 abuts against a corresponding bonding portion 24. In this way, the protective layer 13 may protect the drive circuit layer 11 formed on the second substrate 12 and allow the drive circuit layer 11 to pass through the protective layer 13 and be connected.

In some embodiments, the second substrate 12 is a silicon-based substrate, which may be configured as a single-crystal silicon substrate. The drive circuit layer 11 includes multiple active organic light-emitting diode display devices fabricated using CMOS devices as drive units. The protective layer 13 is configured as an organic protective layer 13 and/or an inorganic protective layer 13 with an insulating property. Specifically, the protective layer 13 may be configured as a SiO₂ layer.

In some embodiments, the drive circuit layer 11 is formed on the second substrate 12, and a portion of the drive circuit layer 11 is exposed, developed, and etched to form the connection portions 111. The protective layer 13 is formed on the drive circuit layer 11, and a height of the protective layer 13 in the axial direction is less than or equal to a height of each connection portion 111, such that at least a portion of the connection portion 111 is exposed outside the protective layer 13 and abuts against the bonding portion 24.

In some embodiments, as shown in FIG. 1, the bonding portion 24 gradually decreases in size from the first substrate 21 toward the second substrate 12, while the connection portion 111 gradually increases in size from the second substrate 12 toward the first substrate 21. The narrow portions of the bonding portion 24 and the connection portion 111 are in contact with each other and are laser-welded to ensure the connection strength between the two.

In some embodiments, some of the bonding portions 24 are connected to the anode film layers 231, and some of the bonding portions 24 is connected to the cathode film layers 233. A corresponding set of a portion of the drive circuit layer 11, the connection portion 111, the bonding portion 24, and the cathode film layer 233 forms an electrical signal conduction path, while another corresponding set of a portion of the drive circuit layer 11, the connection portion 111, the bonding portion 24, and the anode film layer 231 forms another electrical signal conduction path, for transmitting cathode signals and anode signals respectively.

In some embodiments, as shown in FIG. 1, the diameter of the via 211 gradually decreases from a side close to the organic light-emitting diode device 23 to a side away from the organic light-emitting diode device 23, and the diameter of the through hole 131 gradually decreases from a side close to the drive circuit layer 11 to a side away from the drive circuit layer 11. Since the bonding portion 24 gradually decreases in size from the first substrate 21 toward the second substrate 12, the connection portion 111 gradually increases in size from the second substrate 12 toward the first substrate 21, the via 211 and through hole 131 shall form a matching structure with the bonding portion 24 and the connection portion 111 to reduce the risk of voids forming on the sides of the bonding portion 24 and the connection portion 111, thereby achieving better scaling performance.

Furthermore, referring to FIG. 2, the bonding portions 24 include a first bonding portion 241 and a second bonding portion 242, with the second bonding portion 242 located radially outward from the first bonding portion 241; the connection portions 111 include a first connection portion 1111 and a second connection portion 1112, with the second connection portion 1112 located radially outward from the first connection portion 1111; the first bonding portion 241 and the first connection portion 1111 are in contact, and the second bonding portion 242 and the second connection portion 1112 are in contact. The first connection portion 1111, the first bonding portion 241, and the anode film layer 231 are electrically connected, and the second connection portion 1112, the second bonding portion 242, and the cathode film layer 233 are electrically connected.

In the present disclosure, the encapsulation layer 25 includes a first encapsulation layer 251 and a second encapsulation layer 252. The first encapsulation layer 251 is disposed on the cathode film layer 233. In the direction from the cathode film layer 233 to the first substrate 21, the first encapsulation layer 251 extends to the first substrate 21, thereby encapsulating the organic light-emitting diode devices 23 on the first substrate 21. The second encapsulation layer 252 is disposed on the first encapsulation layer 251. In the direction from the cathode film layer 233 to the drive circuit backplate 10, the second encapsulation layer 252 extends onto the drive circuit backplate 10, thereby encapsulating the light-emitting unit carrier plate 20 on the drive circuit backplate 10 and encapsulating the gap between the drive circuit backplate 10 and the light-emitting unit carrier plate 20. A third encapsulation layer 253 is further formed on the second encapsulation layer 252. On one hand, this reduces the thickness of the second encapsulation layer 252 and improves its quality; on the other hand, the third encapsulation layer 253 covers the second encapsulation layer 252 to enhance its encapsulation effect.

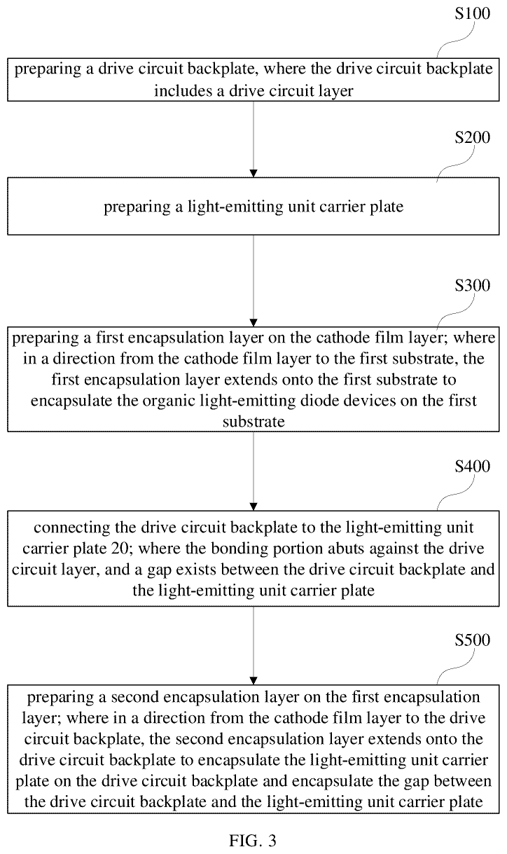

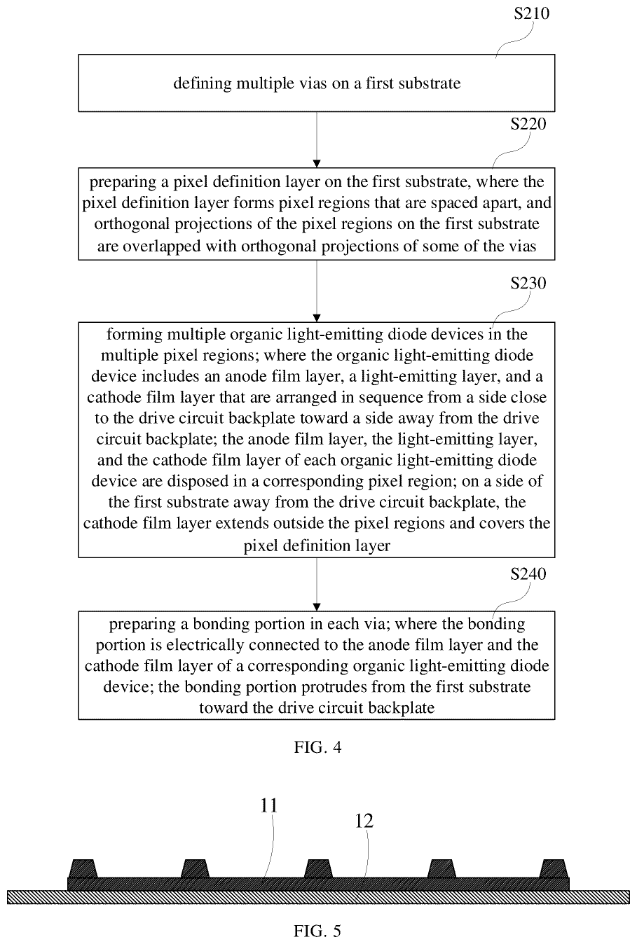

Referring to FIGS. 3 and 4, the present disclosure further provides a manufacturing method of a display panel. The method includes the following operations at blocks illustrated herein.
At block S100: preparing a drive circuit backplate 10, where the drive circuit backplate 10 includes a drive circuit layer 11.

The second substrate 12 is a silicon-based substrate, which may be configured as a single-crystal silicon substrate. The drive circuit layer 11 includes multiple active organic light-emitting diode display devices fabricated using CMOS devices as drive units. The protective layer 13 is configured as an organic protective layer 13 and/or an inorganic protective layer 13 with an insulating property. Specifically, the protective layer 13 may be configured as a SiO₂ layer. Referring to FIG. 5, the drive circuit layer 11 is formed on the second substrate 12, and a portion of the drive circuit layer 11 is exposed, developed, and etched to form the connection portions 111. Referring to FIG. 6, the protective layer 13 is formed on the drive circuit layer 11, and a height of the protective layer 13 in the axial direction is less than or equal to a height of each connection portion 111, such that at least a portion of the connection portion 111 is exposed outside the protective layer 13 and abuts against the bonding portion 24.
At block S200: preparing a light-emitting unit carrier plate 20. The method for preparing the light-emitting unit carrier plate 20 includes the following.
At block S210: defining multiple vias 211 on a first substrate 21.

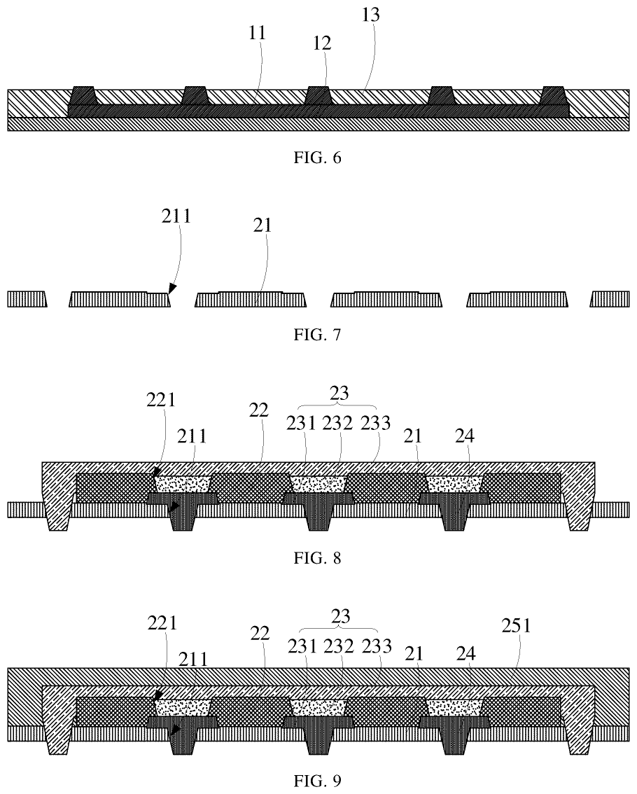

Referring to FIG. 7, the first substrate 21 is a glass substrate, and holes may be prepared on the first substrate 21 by laser drilling, or by exposure, development, and etching.
At block S220: preparing a pixel definition layer 22 on the first substrate 21, where the pixel definition layer 22 forms pixel regions 221 that are spaced apart, and orthogonal projections of the pixel regions 221 on the first substrate 21 are overlapped with orthogonal projections of some of the vias 211.

As shown in FIG. 8, the pixel definition layer 22 includes an inorganic material, which is deposited using plasma-enhanced chemical vapor deposition, followed by a series of processes including exposure, development, and etching to form the pixel regions 221.
At block S230: forming multiple organic light-emitting diode devices 23 in the multiple pixel regions 221; where the organic light-emitting diode device 23 includes an anode film layer 231, a light-emitting layer 232, and a cathode film layer 233 that are arranged in sequence from a side close to the drive circuit backplate 10 toward a side away from the drive circuit backplate 10; the anode film layer 231, the light-emitting layer 232, and the cathode film layer 233 of each organic light-emitting diode device 23 are disposed in a corresponding pixel region 221; on a side of the first substrate 21 away from the drive circuit backplate 10, the cathode film layer 233 extends outside the pixel regions 221 and covers the pixel definition layer 22.

Referring to FIG. 8, during the etching and fabrication process, after forming the pixel regions 221 on the first substrate 21 through exposure, development, and etching, the material of the anode film layer 231 is first vapor-deposited to form the anode film layer 231, followed by vapor-depositing the material of the light-emitting layer 232 to form the light-emitting layer 232, and finally vapor-depositing the material of the cathode film layer 233 to form the cathode film layer 233. The material of cathode film layer 233 is further vapor-deposited on a side opposite to the anode film layer 231 and the light-emitting layer 232, thereby forming a continuous film layer structure on the surface of the pixel definition layer 22 to cover the pixel definition layer 22. In a radial direction, the cathode film layer 233 is vapor-deposited on the outer side of the pixel definition layer 22, and in an axial direction, the cathode film layer 233 extends along the outer side of the pixel definition layer 22. As a result, the cathode film layer 233 designed in this manner may reduce voltage drop and reduce the difficulty of manufacturing the display panel.
At block S240: preparing a bonding portion 24 in each via 211; where the bonding portion 24 is electrically connected to the anode film layer 231 and the cathode film layer 233 of a corresponding organic light-emitting diode device 23; the bonding portion 24 protrudes from the first substrate 21 toward the drive circuit backplate 10.

As shown in FIG. 8, the bonding portion 24 is configured to provide electrical conductivity between the anode film layer 231, the cathode film layer 233, and the drive circuit backplate 10. Since the anode film layer 231 and the cathode film layer 233 require power supply from the drive circuit backplate 10, and the drive circuit backplate 10 is disposed on the side of the first substrate 21 away from the organic light-emitting diode device 23, the bonding portion 24 is required to be protruding toward the drive circuit backplate 10 from the first substrate 21.
At block S300: preparing a first encapsulation layer 251 on the cathode film layer 233; where in a direction from the cathode film layer 233 to the first substrate 21, the first encapsulation layer 251 extends onto the first substrate 21 to encapsulate the organic light-emitting diode devices 23 on the first substrate 21.

As shown in FIG. 9, since the pixel regions 221 are encapsulated and covered by the first encapsulation layer 251, the first encapsulation layer 251 serves to protect the light-emitting layers 232 during the bonding process of the drive circuit backplate 10 and the light-emitting unit carrier plate 20.
At block S400: connecting the drive circuit backplate 10 to the light-emitting unit carrier plate 20; where the bonding portion 24 abuts against the drive circuit layer 11, and a gap exists between the drive circuit backplate 10 and the light-emitting unit carrier plate 20.

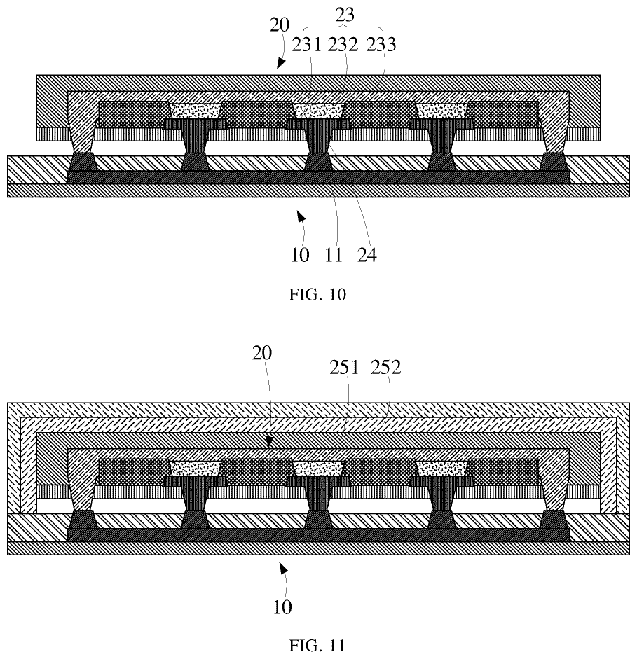

Referring to FIG. 10, the drive circuit backplate 10 can drive the light-emitting unit carrier plate 20 to emit light, with the bonding portion 24 abutting against the drive circuit layer 11, and a gap exists between the drive circuit backplate 10 and the light-emitting unit carrier plate 20, thereby avoiding directly depositing the light-emitting layer 232 on the drive circuit layer 11, and thus improving yield during the manufacturing process and reducing manufacturing costs.
At block S500: preparing a second encapsulation layer 252 on the first encapsulation layer 251; where in a direction from the cathode film layer 233 to the drive circuit backplate 10, the second encapsulation layer 252 extends onto the drive circuit backplate 10 to encapsulate the light-emitting unit carrier plate 20 on the drive circuit backplate 10 and encapsulate the gap between the drive circuit backplate 10 and the light-emitting unit carrier plate 20.

As shown in FIG. 11, after the drive circuit backplate 10 and the light-emitting unit carrier plate 20 are completely connected, the second encapsulation layer 252 encapsulates the light-emitting unit carrier plate 20 on the drive circuit backplate 10 and encapsulates the gap between the drive circuit backplate 10 and the light-emitting unit carrier plate 20. The second encapsulation layer 252 may protect the bonding points between the two substrates, thereby improving the overall reliability of the product and ensuring display quality.

In the present disclosure, since the pixel regions 221 are encapsulated and covered by the first encapsulation layer 251, the first encapsulation layer 251 serves to protect the light-emitting layers 232. After the drive circuit backplate 10 and the light-emitting unit carrier plate 20 are completely connected, the second encapsulation layer 252 encapsulates the light-emitting unit carrier plate 20 on the drive circuit backplate 10 and encapsulates the gap between the drive circuit backplate 10 and the light-emitting unit carrier plate 20. The second encapsulation layer 252 may protect the bonding points between the two substrates, thereby improving the overall reliability of the product and ensuring display quality.

The present disclosure further provides a display device including the display panel described above.

In the present disclosure, unless otherwise explicitly specified or limited, terms such as “arranged with,” “connected,” etc., should be interpreted broadly. For example, they may refer to fixed connections, removable connections, or integral structures; mechanical connections or electrical connections; direct connections or indirect connections via intermediate media; or internal communication between two components or an interactive relationship between two components. For those skilled in the art, the specific meaning of the above terms herein may be understood based on the specific circumstances.

In the description of this specification, the terms “some embodiments” and the like refer to at least one embodiment of the present disclosure that includes the specific features, structures, materials, or characteristics described in the embodiment. In this specification, the illustrative expressions of the above terms are not necessarily directed to the same embodiment or example. Furthermore, the specific features, structures, materials, or characteristics described may be combined in any one or more embodiments or examples in an appropriate manner. Additionally, without being mutually contradictory, those skilled in the art may combine and integrate the different embodiments or examples described in this specification, as well as the features of different embodiments or examples.

Although embodiments of the present disclosure have been shown and described above, it should be understood that the above embodiments are exemplary and not intended to limit the present disclosure. Those skilled in the art may make changes, modifications, replacements, and variations to the above embodiments within the scope of the present disclosure. Therefore, any changes or modifications made in accordance with the claims and description of the present disclosure should be considered within the scope of the present disclosure.

1. A display panel, comprising:
a drive circuit backplate, comprising a drive circuit layer;
a light-emitting unit carrier plate, comprising:
a first substrate, defining a plurality of vias;
a pixel definition layer, disposed on the first substrate; wherein the pixel definition layer forms a plurality of pixel regions that are spaced apart, and orthogonal projections of the plurality of pixel regions on the first substrate are overlapped with orthogonal projections of some of the plurality of vias on the first substrate;
a plurality of organic light-emitting diode devices; wherein each organic light-emitting diode device comprises an anode film layer, a light-emitting layer, and a cathode film layer that are arranged in sequence from a side close to the drive circuit backplate toward a side away from the drive circuit backplate; the anode film layer, the light-emitting layer, and the cathode film layer of each organic light-emitting diode device are disposed in a corresponding pixel region; on a side of the first substrate away from the drive circuit backplate, the cathode film layer extends outside the plurality of pixel regions and covers the pixel definition layer; and
a plurality of bonding portions; wherein each bonding portion is disposed in a corresponding via, and the bonding portion is electrically connected to the anode film layer and the cathode film layer of a corresponding organic light-emitting diode device; the bonding portion protrudes from the first substrate toward the drive circuit backplate; in a case where the drive circuit backplate is connected to the light-emitting unit carrier plate, the bonding portion abuts against the drive circuit layer, and a gap exists between the drive circuit backplate and the light-emitting unit carrier plate; and
an encapsulation layer, comprising: a first encapsulation layer and a second encapsulation layer; wherein the first encapsulation layer is disposed on the cathode film layer, and in a direction from the cathode film layer to the first substrate, the first encapsulation layer extends onto the first substrate to encapsulate the plurality of organic light-emitting diode devices on the first substrate; the second encapsulation layer is disposed on the first encapsulation layer, and in a direction from the cathode film layer to the drive circuit backplate, the second encapsulation layer extends onto the drive circuit backplate to encapsulate the light-emitting unit carrier plate on the drive circuit backplate and encapsulate the gap between the drive circuit backplate and the light-emitting unit carrier plate.

2. The display panel according to claim 1, wherein the encapsulation layer further comprises a third encapsulation layer that is disposed on the second encapsulation layer; in the direction from the cathode film layer to the drive circuit backplate, the third encapsulation layer extends onto the drive circuit backplate.

3. The display panel according to claim 1, wherein in a first direction, a length of the drive circuit backplate is greater than a length of the light-emitting unit carrier plate, and a length of the first substrate is greater than a length of the cathode film layer.

4. The display panel according to claim 1, wherein a diameter of each pixel region gradually increases along a direction from a side close to the first substrate to a side away from the first substrate.

5. The display panel according to claim 1, wherein the drive circuit backplate further comprises a second substrate, a drive circuit layer, and a protective layer; the drive circuit layer is disposed on the second substrate, and the protective layer is disposed on the drive circuit layer; the protective layer defines a plurality of through holes; the drive circuit layer comprises a plurality of connection portions, and each of the plurality of connection portions passes through a corresponding through hole; the plurality of connection portions protrude from the protective layer toward the first substrate, and each of the plurality of connection portions abuts against a corresponding bonding portion.

6. The display panel according to claim 5, wherein each bonding portion gradually decreases in size along a direction from the first substrate toward the second substrate, while a corresponding connection portion gradually increases in size along a direction from the second substrate toward the first substrate.

7. The display panel according to claim 5, wherein the plurality of bonding portions comprise a first bonding portion and a second bonding portion, with the second bonding portion located radially outward from the first bonding portion;
the plurality of connection portions comprise a first connection portion and a second connection portion, with the second connection portion located radially outward from the first connection portion;
the first bonding portion abuts against the first connection portion, and the second bonding portion abuts against the second connection portion.

8. The display panel according to claim 5, wherein a diameter of each via gradually decreases from a side close to the organic light-emitting diode device to a side away from the organic light-emitting diode device, and a diameter of each through hole gradually decreases from a side close to the drive circuit layer to a side away from the drive circuit layer.

9. The display panel according to claim 1, wherein each via is defined in the first substrate by laser drilling.

10. A manufacturing method of a display panel, comprising:
preparing a drive circuit backplate; wherein the drive circuit backplate comprises a drive circuit layer;
preparing a light-emitting unit carrier plate, comprising:
defining a plurality of vias on a first substrate;
preparing a pixel definition layer on the first substrate; wherein the pixel definition layer forms a plurality of pixel regions that are spaced apart, and orthogonal projections of the plurality of pixel regions on the first substrate are overlapped with orthogonal projections of some of the plurality of vias on the first substrate;
forming a plurality of organic light-emitting diode devices in the plurality of pixel regions; wherein each organic light-emitting diode device comprises an anode film layer, a light-emitting layer, and a cathode film layer that are arranged in sequence from a side close to the drive circuit backplate toward a side away from the drive circuit backplate; the anode film layer, the light-emitting layer, and the cathode film layer of each organic light-emitting diode device are disposed in a corresponding pixel region; on a side of the first substrate away from the drive circuit backplate, the cathode film layer extends outside the plurality of pixel regions and covers the pixel definition layer; and
preparing a bonding portion in each via; where the bonding portion is electrically connected to the anode film layer and the cathode film layer of a corresponding organic light-emitting diode device; the bonding portion protrudes from the first substrate toward the drive circuit backplate;
preparing a first encapsulation layer on the cathode film layer; wherein in a direction from the cathode film layer to the first substrate, the first encapsulation layer extends onto the first substrate to encapsulate the plurality of organic light-emitting diode devices on the first substrate;
connecting the drive circuit backplate to the light-emitting unit carrier plate; wherein the bonding portion abuts against the drive circuit layer, and a gap exists between the drive circuit backplate and the light-emitting unit carrier plate; and
preparing a second encapsulation layer on the first encapsulation layer; wherein in a direction from the cathode film layer to the drive circuit backplate, the second encapsulation layer extends onto the drive circuit backplate to encapsulate the light-emitting unit carrier plate on the drive circuit backplate and encapsulate the gap between the drive circuit backplate and the light-emitting unit carrier plate.

11. The manufacturing method according to claim 10, further comprising:
preparing a third encapsulation layer on the second encapsulation layer; wherein in the direction from the cathode film layer to the drive circuit backplate, the third encapsulation layer extends onto the drive circuit backplate.

12. A display device, comprising a display panel;
wherein the display panel comprises:
a drive circuit backplate, comprising a drive circuit layer;
a light-emitting unit carrier plate, comprising:
a first substrate, defining a plurality of vias;
a pixel definition layer, disposed on the first substrate; wherein the pixel definition layer forms a plurality of pixel regions that are spaced apart, and orthogonal projections of the plurality of pixel regions on the first substrate are overlapped with orthogonal projections of some of the plurality of vias on the first substrate;
a plurality of organic light-emitting diode devices; wherein each organic light-emitting diode device comprises an anode film layer, a light-emitting layer, and a cathode film layer that are arranged in sequence from a side close to the drive circuit backplate toward a side away from the drive circuit backplate; the anode film layer, the light-emitting layer, and the cathode film layer of each organic light-emitting diode device are disposed in a corresponding pixel region; on a side of the first substrate away from the drive circuit backplate, the cathode film layer extends outside the plurality of pixel regions and covers the pixel definition layer; and
a plurality of bonding portions; wherein each bonding portion is disposed in a corresponding via, and the bonding portion is electrically connected to the anode film layer and the cathode film layer of a corresponding organic light-emitting diode device; the bonding portion protrudes from the first substrate toward the drive circuit backplate; in a case where the drive circuit backplate is connected to the light-emitting unit carrier plate, the bonding portion abuts against the drive circuit layer, and a gap exists between the drive circuit backplate and the light-emitting unit carrier plate; and
an encapsulation layer, comprising: a first encapsulation layer and a second encapsulation layer; wherein the first encapsulation layer is disposed on the cathode film layer, and in a direction from the cathode film layer to the first substrate, the first encapsulation layer extends onto the first substrate to encapsulate the plurality of organic light-emitting diode devices on the first substrate; the second encapsulation layer is disposed on the first encapsulation layer, and in a direction from the cathode film layer to the drive circuit backplate, the second encapsulation layer extends onto the drive circuit backplate to encapsulate the light-emitting unit carrier plate on the drive circuit backplate and encapsulate the gap between the drive circuit backplate and the light-emitting unit carrier plate.

13. The display device according to claim 12, wherein the encapsulation layer further comprises a third encapsulation layer that is disposed on the second encapsulation layer; in the direction from the cathode film layer to the drive circuit backplate, the third encapsulation layer extends onto the drive circuit backplate.

14. The display device according to claim 12, wherein in a first direction, a length of the drive circuit backplate is greater than a length of the light-emitting unit carrier plate, and a length of the first substrate is greater than a length of the cathode film layer.

15. The display device according to claim 12, wherein a diameter of each pixel region gradually increases along a direction from a side close to the first substrate to a side away from the first substrate.

16. The display device according to claim 12, wherein the drive circuit backplate further comprises a second substrate, a drive circuit layer, and a protective layer; the drive circuit layer is disposed on the second substrate, and the protective layer is disposed on the drive circuit layer; the protective layer defines a plurality of through holes; the drive circuit layer comprises a plurality of connection portions, and each of the plurality of connection portions passes through a corresponding through hole; the plurality of connection portions protrude from the protective layer toward the first substrate, and each of the plurality of connection portions abuts against a corresponding bonding portion.

17. The display device according to claim 16, wherein each bonding portion gradually decreases in size along a direction from the first substrate toward the second substrate, while a corresponding connection portion gradually increases in size along a direction from the second substrate toward the first substrate.

18. The display device according to claim 16, wherein the plurality of bonding portions comprise a first bonding portion and a second bonding portion, with the second bonding portion located radially outward from the first bonding portion;
the plurality of connection portions comprise a first connection portion and a second connection portion, with the second connection portion located radially outward from the first connection portion;
the first bonding portion abuts against the first connection portion, and the second bonding portion abuts against the second connection portion.

19. The display device according to claim 16, wherein a diameter of each via gradually decreases from a side close to the organic light-emitting diode device to a side away from the organic light-emitting diode device, and a diameter of each through hole gradually decreases from a side close to the drive circuit layer to a side away from the drive circuit layer.

20. The display device according to claim 12, wherein each via is defined in the first substrate by laser drilling.
